(19) United States
(12) Patent Application Publication
(10) Pub. No.: US 2016/0148873 A1
(43) Pub. Date: May 26, 2016

(54) ELECTRONIC PACKAGE AND FABRICATION METHOD THEREOF

(71) Applicant: Siliconware Precision Industries Co., Ltd., Taichung (TW)

(72) Inventors: Ching-Wen Chiang, Taichung (TW); Hsien-Wen Chen, Taichung (TW); Kuang-Hsin Chen, Taichung (TW); Chung-Chih Yen, Taichung (TW); Wei-Jen Chang, Taichung (TW)

(21) Appl. No.: 14/833,586

(22) Filed: Aug. 24, 2015

(30) Foreign Application Priority Data
Nov. 25, 2014 (KR) TW103140748

(51) Int. Cl. H01L 23/538; H01L 21/48; H01L 21/768

(52) U.S. Cl. CPC H01L 23/5384; H01L 23/5389; H01L 23/5386; H01L 21/768; H01L 21/486

(57) ABSTRACT

A method for fabricating an electronic package is provided, which includes the steps of: providing a substrate having a cavity and a first via hole; disposing an electronic element in the cavity; forming a dielectric layer on the substrate and the electronic element; forming a circuit layer on the dielectric layer and forming a first conductive portion in the first via hole; forming on the substrate a second via hole communicating with the first via hole, the first and second via holes constituting a through hole; and forming a second conductive portion in the second via hole, the first and second conductive portions constituting a conductor. Since the through hole is formed through a two-step process, the invention can reduce the depth of the via holes and therefore perform laser drilling or etching processes with reduced energy, thereby avoiding damage of the conductive portions and improving the product reliability.

### BACKGROUND OF THE INVENTION

1. Field of the Invention

The present invention relates to packaging processes, and more particularly, to an electronic package and a fabrication method thereof for improving the process yield.

2. Description of Related Art

Through molding via (TMV) technology has been widely applied in semiconductor fields, which mainly involves forming via holes on a surface of an encapsulant by laser drilling so as to increase routing spaces. For example, a fan-out package on package (PoP) structure can be achieved by using TMV technology.

FIGS. 1A to 1F are schematic cross-sectional views showing a method for fabricating an electronic package 1 of a fan-out PoP structure according to the prior art.

Referring to FIG. 1A, an electronic element 10 such as a semiconductor chip is disposed on a release layer 110 of a first carrier 11, and then an encapsulant 13 is formed on the release layer 110 to encapsulate the electronic element 10.

Referring to FIG. 1B, a second carrier 12 having a copper foil 120 is disposed on the encapsulant 13.

Referring to FIG. 1C, the first carrier 11 and the release layer 110 are removed to expose the electronic element 10 and the encapsulant 13.

Referring to FIG. 1D, a laser drilling or reactive ion etching (RIE) process is performed to form a plurality of through holes 130 in the encapsulant 13 around a periphery of the electronic element 10.

Referring to FIG. 1E, a conductive material is filled in the through holes 130 to form a plurality of conductive posts 14. Further, a plurality of redistribution layers (RDLs) 15 are formed on the encapsulant 13 and electrically connected to the conductive posts 14 and the electronic element 10.

Referring to FIG. 1F, the second carrier 12 is removed and a patterning process is performed on the copper foil 120 to form a circuit structure 16. Then, a singulation process is performed to obtain an electronic package 1.

However, since the electronic element 10 is completely encapsulated by the encapsulant 13, warping easily occurs to the overall structure during fabrication or the final singulated product due to a big CTE (Coefficient of Thermal Expansion) mismatch between the encapsulant 13 and the electronic element 10, thus reducing the product reliability.

Further, since the through holes 130 are quite deep and are formed by a one-step process of laser drilling or RIE, the process needs to be performed with high energy. However, the copper foil 120 may be directly destroyed by high energy of the process and consequently, the quality of the circuit structure 16 is adversely affected. As such, the conductive posts 14 cannot be effectively electrically connected to the circuit structure 16 and the reliability of final products is reduced.

Therefore, there is a need to provide an electronic package and a fabrication method thereof so as to overcome the above-described drawbacks.

### SUMMARY OF THE INVENTION

In view of the above-described drawbacks, the present invention provides an electronic package, which comprises: a substrate having opposite first and second sides, wherein a cavity and at least a first via hole are formed on the first side of the substrate and at least a second via hole is formed on the second side of the substrate and communicates with the first via hole, the first via hole and the second via hole constituting a through hole; an electronic element disposed in the cavity of the substrate; a dielectric layer formed on the first side of the substrate and the electronic element; a circuit layer formed on the dielectric layer and electrically connected to the electronic element; and a conductor formed in the through hole, wherein the conductor has a first conductive portion formed in the first via hole and electrically connected to the circuit layer and a second conductive portion formed in the second via hole and electrically connected to the first conductive portion.

In the above-described package, an interface can be formed between the first conductive portion and the second conductive portion.

The present invention further provides a method for fabricating an electronic package, which comprises the steps of: providing a substrate having opposite first and second sides, wherein the substrate has a cavity and at least a first via hole formed on the first side thereof; disposing an electronic element in the cavity of the substrate; forming a dielectric layer on the first side of the substrate and the electronic element; forming a circuit layer on the dielectric layer, wherein the circuit layer is electrically connected to the electronic element and has a first conductive portion extending in the first via hole; forming at least a second via hole on the second side of the substrate, wherein the second via hole communicates with the first via hole, the first via hole and the second via hole constituting a through hole; and forming a second conductive portion in the second via hole, wherein the second conductive portion is electrically connected to the first conductive portion, the first conductive portion and the second conductive portion constituting a conductor in the through hole.

In the above-described method, the cavity can be formed by laser drilling, mechanical drilling or etching.

In the above-described method, the first via hole can be formed by laser drilling, mechanical drilling or etching.

In the above-described method, the cavity can be greater in depth than the first via hole.

In the above-described method, the second via hole can be formed by laser drilling, mechanical drilling or etching.

In the above-described package and method, the substrate can be made of a semiconductor material.

In the above-described package and method, the dielectric layer can further be formed on a wall surface of the first via hole, and the first conductive portion can be formed on the dielectric layer.

In the above-described package and method, an etch stop layer can further be formed in the first via hole, and the first conductive portion can be formed on the etch stop layer. As such, before forming the second conductive portion, the above-described method can further comprise removing the etch stop layer in the through hole so as to expose the first conductive portion.

In the above-described package and method, a conductive block can be formed in the first via hole and positioned between and electrically connecting the first conductive portion and the second conductive portion.

In the above-described package and method, an insulating layer can further be formed on a wall surface of the second via hole, and the second conductive portion can be formed on the insulating layer.

In the above-described package and method, an RDL (Redistribution Layer) structure can further be on the second side of the substrate and electrically connected to the second conductive portion.

Therefore, since the CTE (Coefficient of Thermal Expansion) of the substrate is close to the CTE of the electronic element, the present invention avoids warping of the substrate caused by temperature variation and hence improves the process and product yield.

Further, by forming the through hole through a two-step process, the present invention reduces the depth of the via holes. Therefore, a laser drilling or etching process can be performed with reduced energy so as to prevent damage of the first conductive portion, thus improving the product reliability.

### BRIEF DESCRIPTION OF DRAWINGS

FIGS. 1A to 1F are schematic cross-sectional views showing a method for fabricating an electronic package according to the prior art;

FIGS. 2A to 2H are schematic cross-sectional views showing a method for fabricating an electronic package according to the present invention; and

FIGS. 3A to 3C are schematic cross-sectional views showing a method for fabricating an electronic package according to another embodiment of the present invention.

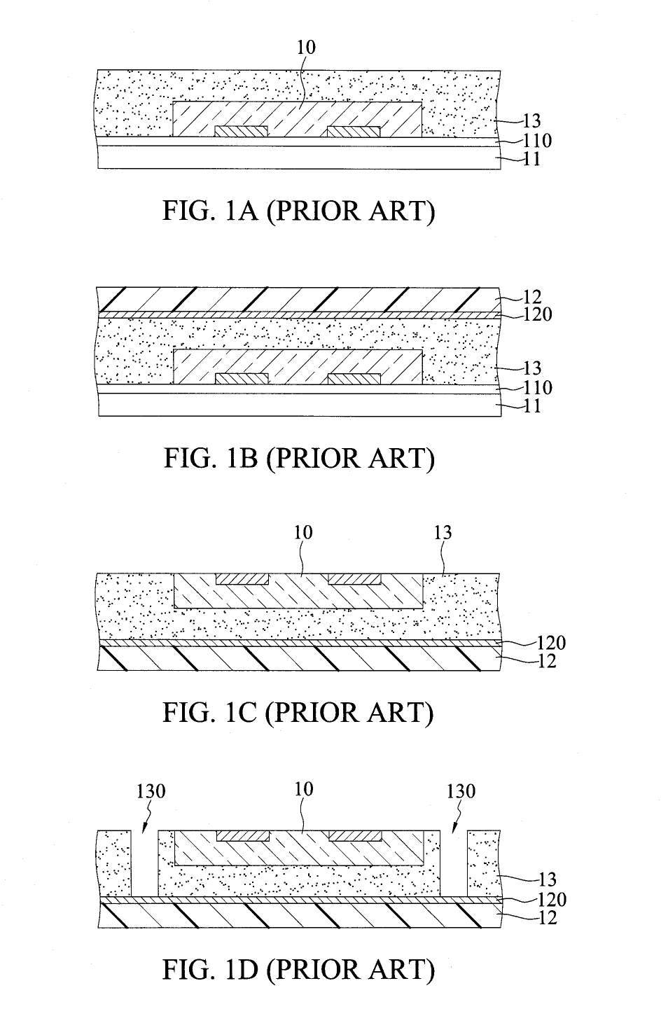

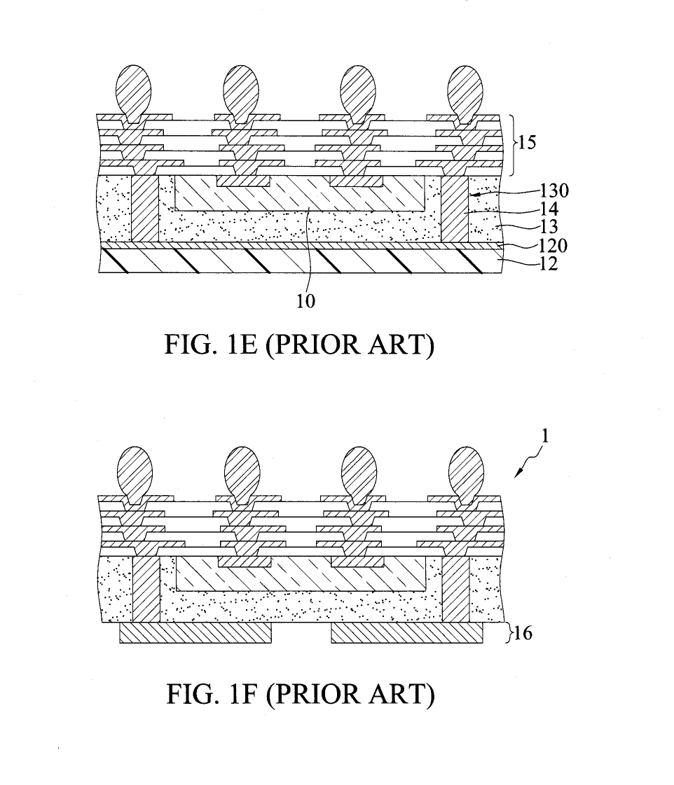

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

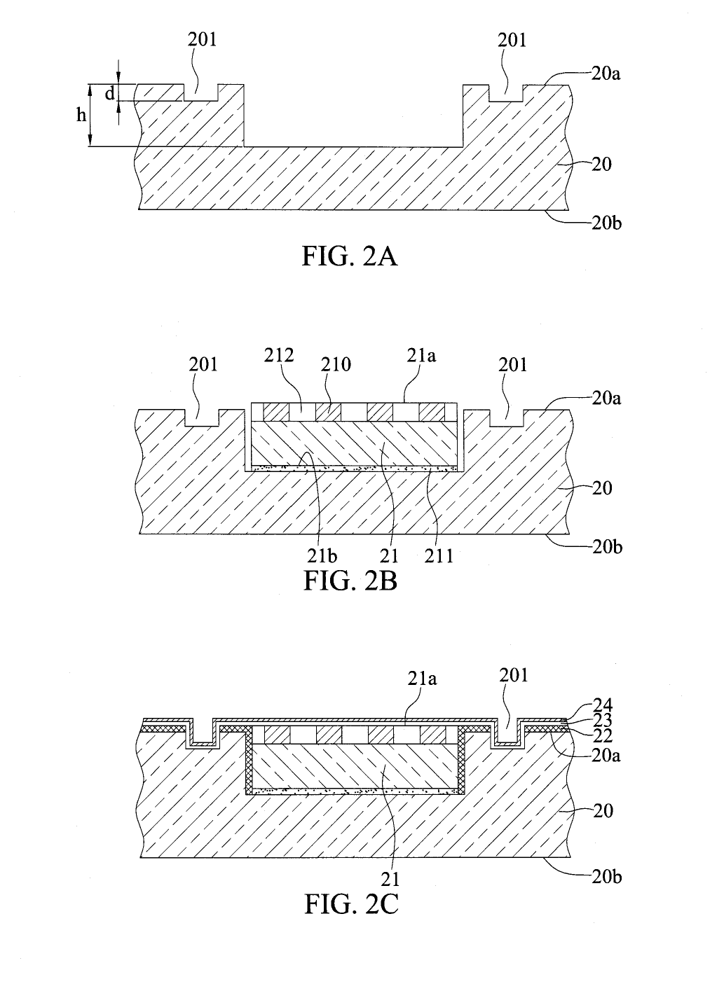

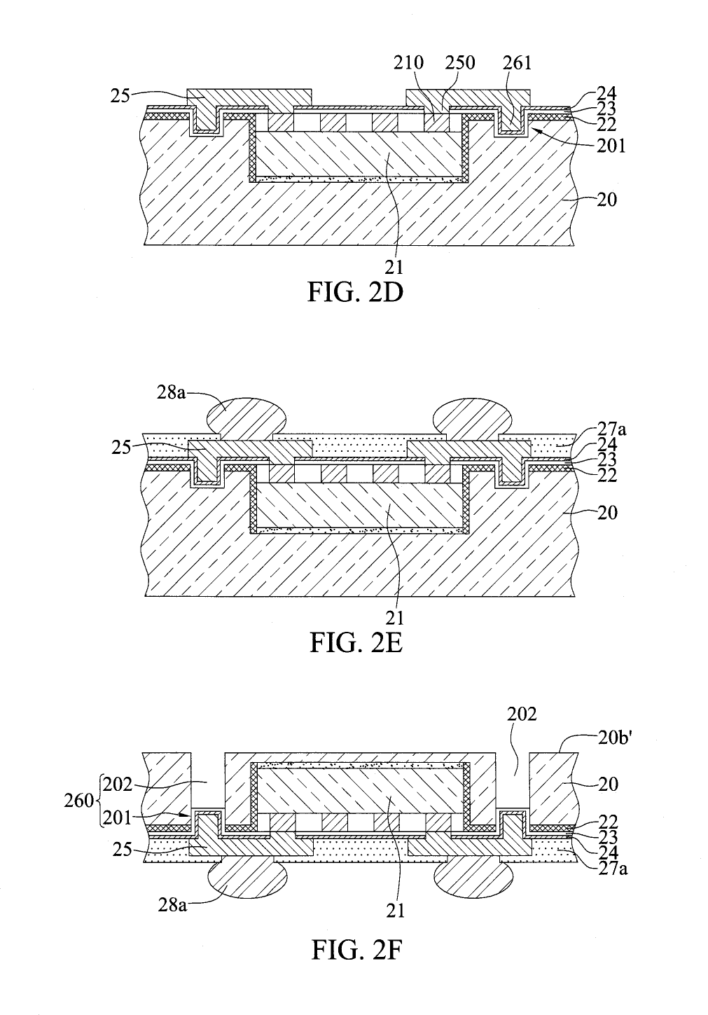

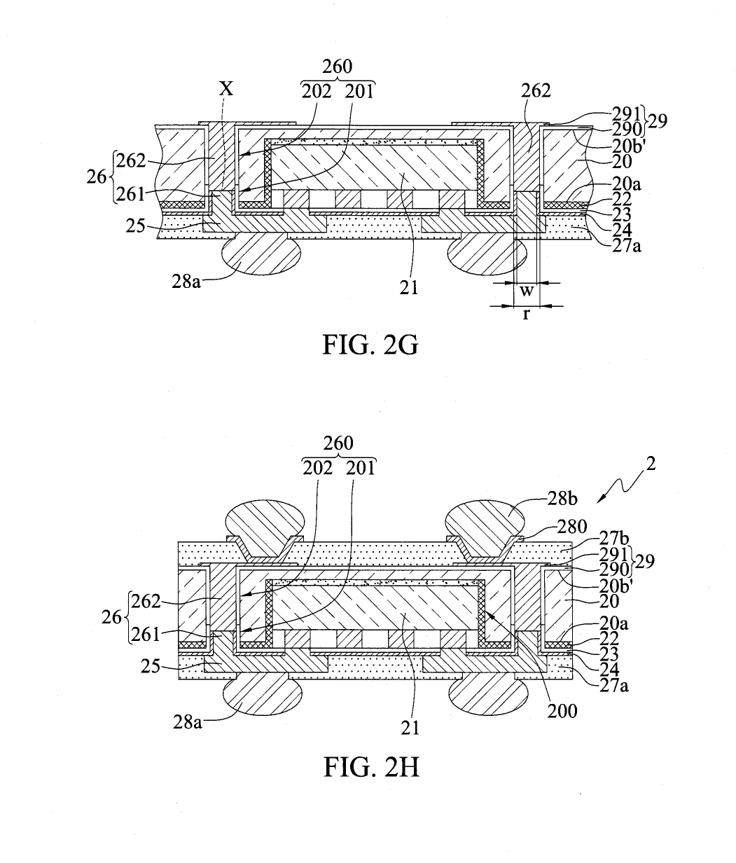

FIGS. 2A to 2H are schematic cross-sectional views showing a method for fabricating an electronic package 2 according to the present invention.

Referring to FIG. 2A, a substrate 20 having opposite first and second sides 20a, 20b is provided, and a cavity 200 and a plurality of first via holes 201 are formed on the first side 20a of the substrate 20.

In the present embodiment, the substrate 20 is made of a semiconductor material such as silicon or glass. The cavity 200 and the first via holes 201 are formed by laser drilling, mechanical drilling or etching (for example, RIE).

The depth h of the cavity 200 is greater than the depth d of the first via holes 201. The first via holes 201 are positioned around a periphery of the cavity 200.

Referring to FIG. 2B, an electronic element 21 is disposed in the cavity 200 of the substrate 20 through a bonding layer 211.

The electronic element 21 is an active element such as a semiconductor chip, a passive element such as a resistor, a capacitor or an inductor, or a combination thereof. In the present embodiment, the electronic element 21 is a semiconductor chip having an active surface 21a with a plurality of electrode pads 210 and an inactive surface 21b opposite to the active surface 21a, and a protection layer 212 is formed on the active surface 21a of the electronic element 21. The electronic element 21 is disposed in the cavity 200 via the inactive surface 21b thereof.

Referring to FIG. 2C, an encapsulant 22 is formed on the first side 20a of the substrate 20 and in the cavity 200 to encapsulate the periphery of the electronic element 21. Then, a dielectric layer 23 is formed on wall surfaces of the first via holes 201 and on the encapsulant 22 and the active surface 21a of the electronic element 21. Thereafter, an etch stop layer 24 is formed on the dielectric layer 23.

In the present embodiment, the encapsulant 22 is made of an insulating material such as polyimide, dry film, epoxy resin or molding compound.

The dielectric layer 23 is made of an inorganic material such as silicon dioxide (SiO₂) or silicon nitride (SiₓN_{y}), or an organic material such as polyimide, polybenzoxazole (PBO) or benzocyclobutene (BCB).

The etch stop layer 24 is made of silicon nitride. As such, the etch solution has a high etch selectivity between silicon and silicon nitride.

Referring to FIG. 2D, an RDL (Redistribution Layer) process is performed to form a circuit layer 25 on the etch stop layer 24. The circuit layer 25 has a plurality of conductive vias 250 penetrating the dielectric layer 23 and the etch stop layer 24 and electrically connected to the electrode pads 210 of the electronic elements 21. Further, the circuit layer 25 has a plurality of first conductive portions 261 extending in the first via holes 201 and positioned on the etch stop layer 24.

In the present embodiment, the circuit layer 25 (including the first conductive portions 261) is formed by electroplating, deposition and so on. In particular, the first conductive portions 261 are metal posts, for example, copper posts.

Referring to FIG. 2E, an insulating layer 27a is formed on the etch stop layer 24 and the circuit layer 25. Further, portions of the circuit layer 25 are exposed from the insulating layer 27a, and a plurality of conductive elements 28a such as solder balls are formed on the exposed portions of the circuit layer 25.

Referring to FIG. 2F, the substrate 20 is partially removed from the second side 20b thereof so as to form a second side 20b′. Then, a plurality of second via holes 202 are formed on the second side 20b′ of the substrate 20 and communicate with the first via holes 201. As such, the first via holes 201 and the corresponding second via holes 202 constitute a plurality of through holes 260.

In the present embodiment, the second via holes 202 are formed by laser drilling, mechanical drilling or etching (for example, RIE).

Referring to FIG. 2G, the etch stop layer 24 and the dielectric layer 23 in the through holes 260 are removed to expose the first conductive portions 261 from the through holes 260. Then, an RDL structure 29 is formed on the second side 20b′ of the substrate 20, and a plurality of second conductive portions 262 are formed in the second via holes 202 and electrically connected to the corresponding first conductive portions 261. As such, the first conductive portions 261 and the corresponding second conductive portions 262 constitute a plurality of conductors 26.

In the present embodiment, the RDL structure 29 has an insulating layer 290 formed on the second side 20b′ of the substrate 20 and a redistribution layer 291 formed on the insulating layer 290 and electrically connected to the second conductive portions 262. In particular, the redistribution layer 291 and the second conductive portions 262 are formed by electroplating, deposition and so on.

The insulating layer 290 further extends on wall surfaces of the second via holes 202, and the second conductive portions 262 are formed on the insulating layer 290.

The width w of the first conductive portions 261 is less than the width r of the second conductive portions 262.

Referring to FIG. 2H, an insulating layer 27b is formed on the RDL structure 29. Further, portions of the redistribution layer 291 are exposed from the insulating layer 27b, and a plurality of conductive elements 28b such as solder balls are formed on the exposed portions of the redistribution layer 291. In addition, a UBM (Under Bump Metallurgy) layer 280 can be formed between the redistribution layer 291 and the conductive elements 28b according to the practical need. Thereafter, a singulation process is performed to obtain an electronic package 2.

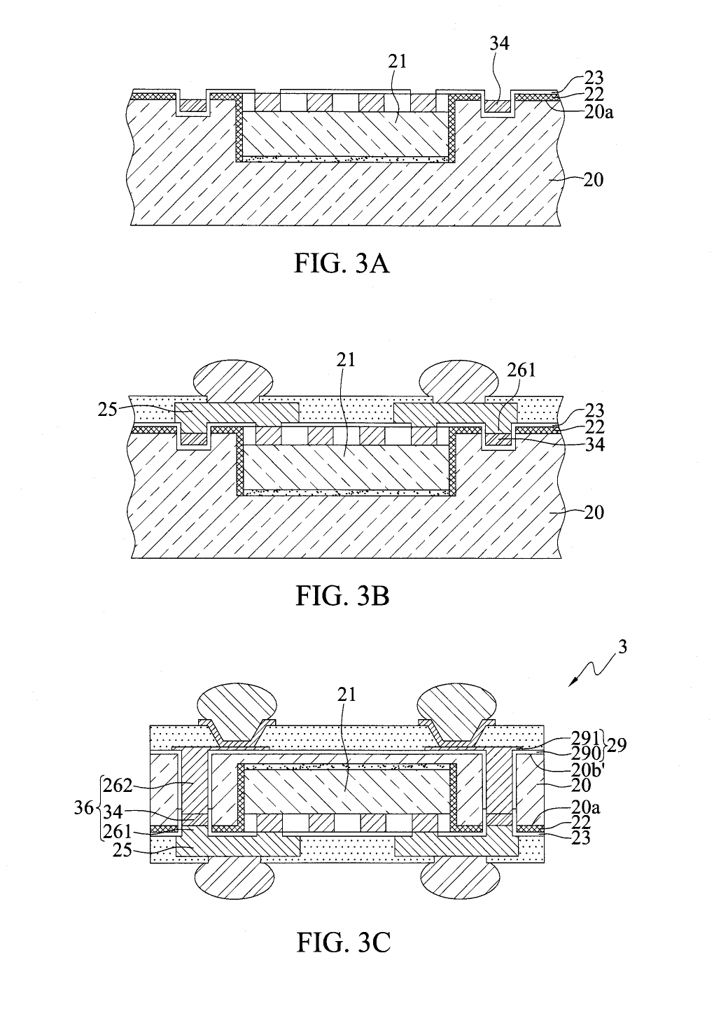

FIGS. 3A to 3C are schematic cross-sectional views showing a method for fabricating an electronic package 3 according to another embodiment of the present invention.

Referring to FIGS. 3A and 3B, before formation of the circuit layer 25, a plurality of conductive blocks 34 are formed on the dielectric layer 23 in the first via holes 201. As such, the first conductive portions 261 are formed on the conductive blocks 34. Therefore, during formation of the second via holes 202, the etch solution has a high etch selectivity between silicon and the conductive blocks 34. Hence, the etch stop layer can be dispensed with.

In the present embodiment, the conductive blocks 34 are made of a solder material.

In subsequent processes, referring to FIG. 3C, the conductive blocks 34 are positioned between and electrically connecting the first conductive portions 261 and the corresponding second conductive portions 262. That is, the conductors 36 further include the conductive blocks 34.

Furthermore, the width of the first conductive portions 261 is equal to the width of the second conductive portions 262.

Therefore, since the substrate 20 is made of a semiconductor material and the CTE of the substrate 20 is close to the CTE of the electronic element 21, the present invention avoids warping of the substrate 20 caused by temperature variation. Hence, the present invention prevents misalignment between the conductive vias 250 and the electrode pads 210 of the electronic element 21 and avoids damage of the electronic element 21, thereby improving the process and product yield.

Further, by forming the through holes 260 through a two-step process (i.e., forming the first via holes 201 and the second via holes 202), the present invention reduces the depth of the via holes (i.e., the first via holes 201 and the second via holes 202). Therefore, a laser drilling or RIE process can be performed with reduced energy so as to prevent damage of the first conductive portions 261 during formation of the second via holes 202, thus allowing the conductors 26 to effectively electrically connect the circuit layer 25 and the redistribution layer 291 and improving the product reliability.

Furthermore, during formation of the second via holes 202, the etch stop layer 24 or conductive blocks 34 can serve as a stop layer for etching (dry etching) or laser so as to prevent damage of the first conductive portions 261.

The present invention further provides an electronic package 2, 3, which has: a substrate 20 having opposite first and second sides 20a, 20b′, wherein a cavity 200 and at least a first via hole 201 are formed on the first side 20a of the substrate 20 and at least a second via hole 202 is formed on the second side 20b′ of the substrate 20 and communicates with the first via hole 201, the first via hole 201 and the second via hole 202 constituting a through hole 260; an electronic element 21 disposed in the cavity 200 of the substrate 20; a dielectric layer 23 formed on the first side 20a of the substrate 20 and the electronic element 21; a circuit layer 25 formed on the dielectric layer 23 and electrically connected to the electronic element 21; and a conductor 26, 36 formed in the through hole 260, wherein the conductor 26 has a first conductive portion 261 formed in the first via hole 201 and electrically connected to the circuit layer 25 and a second conductive portion 262 formed in the second via hole 202 and electrically connected to the first conductive portion 261.

The substrate 20 can be made of a semiconductor material.

The dielectric layer 23 can further be formed on a wall surface of the first via hole 201, and the first conductive portion 261 can be formed on the dielectric layer 23.

In an embodiment, an interface X is formed between the first conductive portion 261 and the second conductive portion 262.

In an embodiment, the electronic package 2 further has an etch stop layer 24 formed on the dielectric layer 23 on the wall surface of the first via hole 201, and the first conductive portion 261 is formed on the etch stop layer 24.

In an embodiment, the conductor 36 further has a conductive block 34 formed in the first via hole 201 and positioned between and electrically connecting the first conductive portion 261 and the second conductive portion 262.

In an embodiment, the electronic package 2, 3 further has an insulating layer 290 formed on a wall surface of the second via hole 202, and the second conductive portion 262 is formed on the insulating layer 290.

In an embodiment, the electronic package 2, 3 further has an RDL structure 29 formed on the second side 20b′ of the substrate 20 and electrically connected to the second conductive portion 262.

Therefore, since the CTE of the substrate is close to the CTE of the electronic element, the present invention avoids warping of the substrate caused by temperature variation and hence improves the process and product yield.

Further, by forming the through hole through a two-step process, the present invention reduces the depth of the via holes. Therefore, a laser drilling or RIE process can be performed with reduced energy so as to prevent damage of the first conductive portion, thus improving the product reliability.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An electronic package, comprising:
a substrate having opposite first and second sides, wherein a cavity and at least a first via hole are formed on the first side of the substrate and at least a second via hole is formed on the second side of the substrate and communicates with the first via hole, the first via hole and the second via hole constituting a through hole;
an electronic element disposed in the cavity of the substrate;
a dielectric layer formed on the first side of the substrate and the electronic element;
a circuit layer formed on the dielectric layer and electrically connected to the electronic element; and
a conductor formed in the through hole, wherein the conductor has a first conductive portion formed in the first via hole and electrically connected to the circuit layer and a second conductive portion formed in the second via hole and electrically connected to the first conductive portion.

2. The package of claim 1, wherein the substrate is made of a semiconductor material.

3. The package of claim 1, wherein the dielectric layer is further formed on a wall surface of the first via hole, and the first conductive portion is formed on the dielectric layer.

4. The package of claim 1, wherein an interface is formed between the first conductive portion and the second conductive portion.

5. The package of claim 1, further comprising an etch stop layer formed on a wall surface of the first via hole, wherein the first conductive portion is formed on the etch stop layer.

6. The package of claim 1, wherein a conductive block is formed in the first via hole and positioned between and electrically connecting the first conductive portion and the second conductive portion.

7. The package of claim 1, further comprising an insulating layer formed on a wall surface of the second via hole, wherein the second conductive portion is formed on the insulating layer.

8. The package of claim 1, further comprising an RDL (Redistribution Layer) structure formed on the second side of the substrate and electrically connected to the second conductive portion.

9. A method for fabricating an electronic package, comprising the steps of:
providing a substrate having opposite first and second sides, wherein the substrate has a cavity and at least a first via hole formed on the first side thereof;
disposing an electronic element in the cavity of the substrate;
forming a dielectric layer on the first side of the substrate and the electronic element;
forming a circuit layer on the dielectric layer, wherein the circuit layer is electrically connected to the electronic element and has a first conductive portion extending in the first via hole;
forming at least a second via hole on the second side of the substrate, wherein the second via hole communicates with the first via hole, the first via hole and the second via hole constituting a through hole; and
forming a second conductive portion in the second via hole, wherein the second conductive portion is electrically connected to the first conductive portion, the first conductive portion and the second conductive portion constituting a conductor in the through hole.

10. The method of claim 9, wherein the substrate is made of a semiconductor material.

11. The method of claim 9, wherein the cavity is formed by laser drilling, mechanical drilling or etching.

12. The method of claim 9, wherein the first via hole is formed by laser drilling, mechanical drilling or etching.

13. The method of claim 9, wherein the cavity is greater in depth than the first via hole.

14. The method of claim 9, wherein the dielectric layer is further formed on a wall surface of the first via hole, and the first conductive portion is formed on the dielectric layer.

15. The method of claim 9, wherein the second via hole is formed by laser drilling, mechanical drilling or etching.

16. The method of claim 9, further comprising forming an etch stop layer in the first via hole, wherein the first conductive portion is formed on the etch stop layer.

17. The method of claim 16, before forming the second conductive portion, further comprising removing the etch stop layer in the through hole so as to expose the first conductive portion.

18. The method of claim 9, before forming the circuit layer, further comprising forming a conductive block in the first via hole, wherein the first conductive portion is formed on the conductive block.

19. The method of claim 9, further comprising forming an insulating layer on a wall surface of the second via hole, wherein the second conductive portion is formed on the insulating layer.

20. The method of claim 9, further comprising forming an RDL (Redistribution Layer) structure on the second side of the substrate, wherein the RDL structure is electrically connected to the second conductive portion.
